(19) United States
(12) Patent Application Publication
(10) Pub. No.: US 2026/0371854 A1
(43) Pub. Date: Nov. 19, 2026

(54) DISPLAY SUBSTRATE, METHOD FOR MANUFACTURING THE SAME AND DISPLAY APPARATUS

(71) Applicants: Yunnan Invensight Optoelectronics Technology Co., Ltd., Kunming, Yunnan (CN); BOE Technology Group Co., Ltd., Beijing (CN); Beijing BOE Technology Development Co., Ltd., Beijing (CN)

(72) Inventors: Yunfang GONG, Beijing (CN); Yinhu HUANG, Beijing (CN); Dacheng ZHANG, Beijing (CN)

(21) Appl. No.: 19/147,989

(22) PCT Filed: Jun. 11, 2024
(86) PCT No.: PCT/CN2024/098490

§ 371 Date: Jul. 14, 2025

(30) Foreign Application Priority Data
Jul. 27, 2023 (CN) 202310934467.2

(51) Int. Cl. H10K 59/122; H10K 59/12; H10K 59/80; H10K 102/00

(52) U.S. Cl. CPC H10K 59/122; H10K 59/1201; H10K 59/80515; H10K 2102/351

(57) ABSTRACT

The present disclosure provides a display substrate, a method for manufacturing the same, and a display apparatus, where the display substrate (10) includes: a base substrate (100), a pixel defining layer (110) and a plurality of light emitting devices (120). The pixel defining layer (110) includes a plurality of pixel openings (114). Each light emitting device (120) includes a first electrode (121), an organic light emitting functional layer (122), and a second electrode (123), which are stacked, a periphery of an upper port of each pixel opening (114) is provided with a protrusion structure (130) surrounding the pixel opening (114), and the protrusion structure (130) is configured to block a leakage path from the first electrode (121) exposed at the pixel opening (114) to a spacing region between the adjacent light emitting devices (120).

### CROSS REFERENCE TO RELATED APPLICATIONS

The present application claims the priority of the Chinese Patent Application No. 2023109344672 filed on Jul. 27, 2023, the content of which is incorporated herein by reference in its entirety.

### TECHNICAL FIELD

The present disclosure relates to the field of display technology, in particular to a display substrate, a method for manufacturing a display substrate and a display apparatus.

### BACKGROUND

A micro-OLED (micro organic light emitting diode) micro-display device has the characteristics of self-luminescence, thin thickness, light weight, large viewing angle, short response time, high light emitting efficiency, easy realization of high PPI (pixel density), low power consumption and the like, and is widely applied to display products. However, the micro-OLED micro-display device still has some problems that the display effect is affected, such as color crosstalk interference among pixels.

### SUMMARY

According to a first aspect of the present disclosure, there is provided a display substrate including: a base substrate; a pixel defining layer on the base substrate and including a plurality of pixel openings; and a plurality of light emitting devices, wherein each light emitting device is located at one pixel opening, each light emitting device includes a first electrode, an organic light emitting functional layer, and a second electrode, which are stacked, the first electrodes of any two adjacent light emitting devices are spaced apart from each other in a spacing region between the two adjacent light emitting devices, and the organic light emitting functional layer covers a corresponding pixel opening and extends to the spacing region; wherein at least a part of the first electrode is exposed at a lower port of the corresponding pixel opening, a periphery of an upper port of each pixel opening is provided with a protrusion structure surrounding the pixel opening, the protrusion structure is located between the pixel opening and the spacing region, the protrusion structure is made of an insulating material, and the protrusion structure is configured to block a leakage path from the first electrode exposed at the pixel opening to the spacing region.

According to a second aspect of the present disclosure, there is further provided a display substrate including: a base substrate; a pixel defining layer on the base substrate and including a plurality of pixel openings; and a plurality of light emitting devices, where each light emitting device is located at one pixel opening, each light emitting device includes a first electrode, an organic light emitting functional layer, and a second electrode, which are stacked, the first electrodes of any two adjacent light emitting devices are spaced apart from each other in a spacing region between the two adjacent light emitting devices, and the organic light emitting functional layer covers a corresponding pixel opening and extends to the spacing region; where at least a part of the first electrode is exposed at a lower port of the pixel opening, a periphery of an upper port of each pixel opening is provided with a protrusion structure surrounding the pixel opening, each protrusion structure is formed by an accumulation of a polymer generated during etching the corresponding pixel opening, and the protrusion structure is configured to block a leakage path from the first electrode exposed at the pixel opening to the spacing region.

According to a third aspect of the present disclosure, there is further provided a display apparatus including the display substrate provided in the first aspect or the second aspect of the present disclosure.

According to a fourth aspect of the present disclosure, there is further provided a method for manufacturing a display substrate, including: providing a base substrate; forming first electrodes of a plurality of light emitting devices on the base substrate, where the first electrodes of any two adjacent light emitting devices are spaced apart from each other in a spacing region between the two adjacent light emitting devices; forming a pixel defining layer on the first electrodes and including a plurality of pixel openings, where each pixel opening corresponds to one light emitting device, at least a part of the first electrode of the light emitting device is exposed at a lower port of the pixel opening corresponding to the light emitting device, a periphery of an upper port of each pixel opening is provided with a protrusion structure surrounding the pixel opening, and the protrusion structure is made of an insulating material; forming organic light emitting functional layers of the plurality of light emitting devices on the pixel defining layer, where each organic light emitting functional layer covers the corresponding pixel opening and extends to the spacing region, and the protrusion structure is configured to block a leakage path from the first electrode exposed at the pixel opening to the spacing region; and forming second electrodes of the plurality of light emitting devices on the organic light emitting functional layers.

The above description is only an overview of technical solutions provided by some embodiments of the present disclosure. In order to understand the technical means of the embodiments of the present disclosure more clearly, the embodiments of the present disclosure may be implemented according to the content of the description. In order to make the embodiments of the present disclosure more clearly understood, the detail description of embodiments will be specifically described below.

### BRIEF DESCRIPTION OF FIGURES

In order to more clearly illustrate the technical solutions in the present disclosure, the drawings used for describing the embodiments will be briefly described below. Obviously, the drawings in the following description are only some embodiments of the present disclosure, and other drawings may be obtained by one of ordinary skill in the art according to the drawings without creative efforts.

FIG. 1 illustrates a schematic diagram of a leakage path of a display substrate according to some embodiments of the present disclosure;

FIG. 2 illustrates a schematic cross-sectional view of a display substrate according to some embodiments of the present disclosure;

FIG. 3 illustrates a schematic diagram of an arrangement of pixels of a display substrate according to some embodiments of the present disclosure;

FIG. 4 illustrates a schematic plan view of a protrusion structure according to some embodiments of the present disclosure;

FIG. 5 illustrates a schematic diagram of a structure of a light emitting device according to some embodiments of the present disclosure;

FIG. 6 illustrates a plan micrograph of a pixel opening according to some embodiments of the present disclosure;

FIG. 7 illustrates a cross-sectional micrograph at a pixel opening according to some embodiments of the present disclosure;

FIG. 8 illustrates a flow chart of a method for manufacturing a display substrate according to some embodiments of the present disclosure;

FIG. 9 illustrates a schematic diagram of a structure with a patterned photoresist material layer according to some embodiments of the present disclosure;

FIG. 10 illustrates a schematic diagram of a structure after being etched by a dry etching method according to some embodiments of the present disclosure;

FIG. 11 illustrates a schematic diagram of a structure after the photoresist being removed according to some embodiments of the present disclosure; and

FIG. 12 illustrates a schematic diagram of a display apparatus according to some embodiments of the present disclosure.

### DETAIL DESCRIPTION

Exemplary embodiments of the present disclosure will be described in more detail below with reference to the accompanying drawings. While exemplary embodiments of the present disclosure are shown in the drawings, it should be understood that the present disclosure may be embodied in various forms and should not be limited by the embodiments set forth herein. Rather, these embodiments are provided so that this disclosure will be understood thoroughly and completely, and will fully convey the scope of the present disclosure to one ordinary skill in the art.

It should be noted that the phrase “a plurality of” used in this disclosure means two or more. The word “include”, “comprise”, or the like, means that the element or item preceding the word contains the element or item listed after the word and its equivalent, but does not exclude the presence of other elements or items. The terms “upper”, “lower”, “left”, “right”, and the like are used only for indicating relative positional relationships, and when the absolute position of an object being described is changed, the relative positional relationships may also be changed accordingly.

It will be understood that when a layer or an element is referred to as being on another layer or substrate, the layer or element may be directly on the other layer or substrate or intervening layers may alternatively be present therebetween.

Micro-OLED (micro organic light emitting diode) micro-display devices are widely used in display products, such as a wearable VR (virtual reality) device, an AR (augmented reality) device, or the like. However, it is found in the actual production process that in the micro-OLED (micro organic light emitting diode) micro-display device, color crosstalk interference occurs among pixels, which affects the display effect. Therefore, it is necessary to eliminate the color crosstalk interference to improve the display effect.

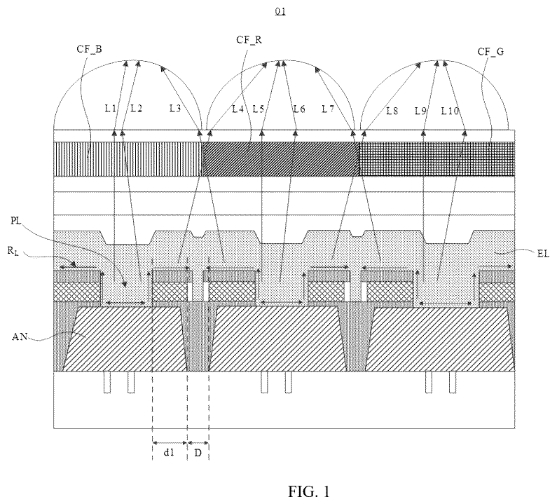

FIG. 1 illustrates a schematic diagram of a leakage path of a display substrate according to some embodiments of the present disclosure. As shown in FIG. 1, it is found by analyzing that one of the reasons for the color crosstalk interference is as follows. A first electrode AN (e.g., an anode) in a display substrate 01 is formed by patterning, and an ideal current path is along a direction perpendicular to an organic light emitting functional layer EL covering a pixel opening PL. However, in practical application scenarios, in the micro-OLED micro-display device, a distance dl between each pixel opening PL and a corresponding spacing region between adjacent pixels is small, for example, as small as in an order of micrometer (um). Therefore, after the first electrode AN is powered on, in a transverse direction, the spacing region between the adjacent pixels is easily conductive due to the leakage of the first electrode AN, that is, a leakage circuit (such as a leakage path RL shown in FIG. 1) is formed between the first electrode AN and the spacing region, so that the organic light emitting functional layer EL covering between the adjacent pixels is conductive to emit light, thereby causing a color cross problem among the pixels and affecting the display effect.

FIG. 1 shows 10 exemplary light rays L1 to L10, where L1, L2, L5, L6, L9 and L10 are light rays emitted normally from the pixels, and L3, L4, L7 and L8 are light rays causing color crosstalk emitted by the organic light emitting functional layer in the spacing region between the pixels due to the above leakage current. As shown in FIG. 1, L3 sequentially passes through a red filter unit CF_R and a blue filter unit CF B to be emitted, L4 sequentially passes through the blue filter unit CF_B and the red filter unit CF_R to be emitted, L7 sequentially passes through a green filter unit CF_G and the red filter unit CF_R to be emitted, and L8 sequentially passes through the red filter unit CF_R and the green filter unit CF_G to be emitted, so that a color crosstalk occurs among the pixels, and a display effect is affected.

Therefore, some embodiments of the present disclosure provide a display substrate, a method for manufacturing the display substrate, and a display apparatus, in which an insulating protrusion structure surrounding a pixel opening is disposed at the periphery of an upper port of the pixel opening, and the protrusion structure is located between the pixel opening and a spacing region between adjacent light emitting devices, so that a leakage path from the first electrode exposed at the pixel opening to the spacing region between adjacent pixels can be effectively blocked, which is beneficial to reducing the color crosstalk interference of light among pixels, thus improving the display effect.

Hereinafter, a display substrate provided in some embodiments of the present disclosure will be described in detail with reference to the accompanying drawings.

FIG. 2 illustrates a schematic cross-sectional view of a display substrate according to some embodiments of the present disclosure. As shown in FIG. 2, some embodiments of the present disclosure provide a display substrate 10, and the display substrate 10 may include: a base substrate 100, and a pixel defining layer 110 and a plurality of light emitting devices 120 on the base substrate 100. The pixel defining layer 110 includes a plurality of pixel openings 114, and each light emitting device 120 is located at one of the pixel openings 114. Each light emitting device 120 includes a first electrode 121, an organic light emitting functional layer 122, and a second electrode 123, which are stacked, the first electrodes 121 of any two adjacent light emitting devices 120 are spaced apart from each other in a spacing region between the two adjacent light emitting devices 120, and each organic light emitting functional layer 122 covers the pixel opening 114 and extends to the spacing region between the adjacent light emitting devices 120. At least a part of the first electrode 121 is exposed at a lower port of each pixel opening 114. A periphery of an upper port of each pixel opening 114 is provided with a protrusion structure 130 surrounding the pixel opening 114. The protrusion structure 130 is located between the pixel opening 114 and the spacing region between the adjacent light emitting devices 120, the protrusion structure 130 is made of an insulating material, and the protrusion structure 130 is configured to block a leakage path from the first electrode 121 exposed at the pixel opening 114 to the spacing region.

It should be noted that the lower port of the pixel opening 114 is a port close to the base substrate 100, and the upper port of the pixel opening 114 is a port away from the base substrate 100. For example, as shown in FIG. 2, a region of each light emitting device 120 may be defined by an edge of the first electrode 121 as a demarcation line, thereby defining the spacing region between the adjacent light emitting devices 120. Alternatively, in other embodiments, the spacing region between the adjacent light emitting devices 120 may be defined in other manners. For example, the pixel openings 114 may also be used to define light emitting regions of the light emitting devices 120, and a region between the adjacent pixel openings 114 is used as the spacing region between the adjacent light emitting devices 120, which is not limited in this embodiment.

In the embodiment shown in FIG. 2, the protrusion structure 130 surrounding each pixel opening 114 is disposed at the periphery of the upper port of the pixel opening 114, and the protrusion structure 130 is made of the insulating material, so that the leakage path from the first electrode 121 exposed at the pixel opening 114 to the spacing region between the adjacent light emitting devices 120 can be effectively blocked, which is beneficial to reducing the risk that the organic light emitting functional layer 122 in the spacing region between the adjacent pixels emits light, and reducing color crosstalk interference among pixels, so as to improve the display effect. For example, the leakage path RL shown in FIG. 1 is blocked by the protrusion structure 130, so that the spacing region between the adjacent pixels can be effectively prevented from emitting light (such as light rays L3, L4, L7 and L8 shown in FIG. 1) due to the leakage current of the first electrode 121, which is beneficial to eliminating the color crosstalk interference among pixels.

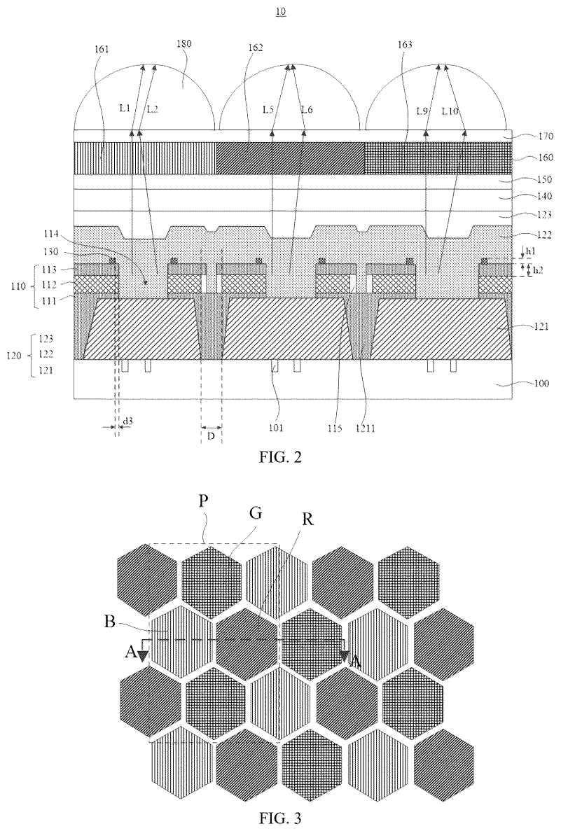

FIG. 3 illustrates a schematic diagram of an arrangement of pixels of a display substrate 10 according to some embodiments of the present disclosure. FIG. 2 may be a cross-sectional view of a structure in FIG. 3 taken along a line A-A. For example, as shown in FIG. 3, the display substrate 10 may include: a plurality of pixel units P repeatedly arranged, each pixel unit includes a plurality of sub-pixels, each sub-pixel emitting light of one color. Each sub-pixel is provided with one of the light emitting devices 120. For example, each pixel unit P may include: two green sub-pixels G, one red sub-pixel R, and one blue sub-pixel B, each sub-pixel corresponds to one light emitting device 120 and one pixel opening 114. The pixel opening 114 corresponding to each sub-pixel is provided with the protrusion structure 130 surrounding the periphery of the pixel opening 114. It should be noted that the arrangement of the pixels and the shape of the sub-pixel shown in FIG. 3 are only illustrative, and in other embodiments, other arrangements may be adopted, which is not limited in this embodiment.

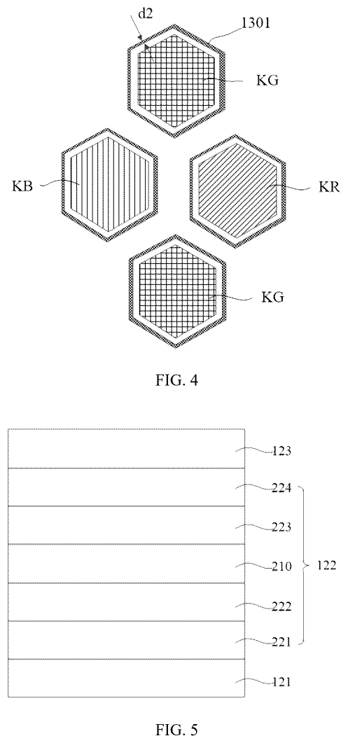

FIG. 4 illustrates a schematic plan view of a protrusion structure according to some embodiments of the present disclosure. In FIG. 4, taking a single pixel unit P shown in FIG. 3 as an example, KG represents an orthographic projection region of the upper port of the pixel opening 114 corresponding to the green sub-pixel G on the base substrate 100, KR represents an orthographic projection region of the upper port of the pixel opening 114 corresponding to the red sub-pixel R on the base substrate 100, and KB represents an orthographic projection region of the upper port of the pixel opening 114 corresponding to the blue sub-pixel B on the base substrate 100.

As shown in FIG. 4, in some embodiments of the present disclosure, an orthographic projection 1301 of the protrusion structure 130 on the base substrate 100 may have a closed ring shape, that is, an anti-leakage protection structure is formed at the periphery of the upper port of the pixel opening 114 to block a leakage path between the first electrode 121 and the spacing region between the adjacent light emitting devices 120, so as to prevent the organic light emitting functional layer 122 covering the spacing region between the adjacent light emitting devices from being conductive to emit light. It should be noted that the closed ring shape shown in FIG. 4 is merely an example, and a planar shape of the closed ring may be determined according to a shape of an orthographic projection of the upper port of the pixel opening 114 on the base substrate 100. For example, the planar shape may be a triangular ring, a prismatic ring, a rectangular ring, a trapezoidal ring, a pentagonal ring, a regular hexagonal ring, a circular ring, or an elliptical ring, or the like. It should be noted that if the shape of the orthographic projection of the protrusion structure 130 on the base substrate 100 is a regular hexagonal ring, the shape of the orthographic projection is substantially a regular hexagonal ring, such as a standard regular hexagonal ring, or an approximately regular hexagonal ring with a chamfer, a sawtooth or a round corner, which is not limited in this embodiment.

In some embodiments of the present disclosure, a ratio (d2: D) of a ring width d2 of the closed ring shape to a width D of the spacing region between the adjacent light emitting devices 120 may range from one fiftieth to one two-hundredth. For example, d2: D may be 1:50, 1:100, 1:150 or 1:200. In some embodiments of the present disclosure, the ring width d2 of the closed ring shape may range from 10 nm to 30 nm, for example, 10 nm, 15 nm, 20 nm, 25 nm or 30 nm, so as to fully block the leakage path.

In some embodiments of the present disclosure, due to process limitations, a distance d3 between the protrusion structure 130 and the pixel opening 114 surrounded by the protrusion structure 130 may be in a range from 10 nm to 30 nm, for example, 10 nm, 15 nm, 20 nm, 25 nm, or 30 nm. The less the distance between the protrusion structure 130 and the pixel opening 114 is, the better the effect of the protrusion structure 130 increasing the physical insulation height of the pixel defining layer 110 is, and the earlier the leakage path from the first electrode 121 exposed at the pixel opening 114 to the spacing region between the adjacent light emitting devices 120 being blocked, therefore, it is beneficial to further reducing the light emitting of the organic light emitting functional layer 122 between the adjacent pixels, thereby reducing the crosstalk interference among pixels. The farther the protrusion structure 130 is from the pixel opening 114, the weaker the leakage blocking effect is, and the leakage current may jump over the protrusion structure 130 to continue to propagate.

FIG. 5 illustrates a schematic diagram of a structure of a light emitting device 120 according to some embodiments of the present disclosure. As shown in FIG. 5, the light emitting device 120 may include: the first electrode 121, the organic light emitting functional layer 122, and the second electrode 123 stacked sequentially in a direction away from the base substrate 100. For example, the light emitting device 120 may be an organic light emitting diode, and the organic light emitting functional layer 122 may include: an organic light emitting layer 210 and an organic functional layer.

In some embodiments of the present disclosure, the organic light emitting layer 210 may be divided into light emitting layers of different colors, such as a red light emitting layer, a green light emitting layer, and a blue light emitting layer. The structure of the organic light emitting layer 210 is determined according to the color of light emitted by the light emitting device 120 in the practical application scenario, which is not limited in this embodiment. In some embodiments of the present disclosure, the light emitting device 120 may be a white light emitting device, and in this case, the organic light emitting layer 210 may include: the red light emitting layer, the green light emitting layer and the blue light emitting layer to form composite white light. Alternatively, for the red light emitting device 120, the organic light emitting layer 210 may include the red light emitting layer; for the green light emitting device, the organic light emitting layer 210 may include the green light emitting layer; and for the blue light emitting device, the organic light emitting layer 210 may include the blue light emitting device.

In some embodiments of the present disclosure, the organic functional layer may include one or more of a hole injection layer, a hole transport layer, an electron blocking layer, an electron injection layer, an electron transport layer, and a hole blocking layer.

One of the first electrode 121 and the second electrode 123 is an anode, and the other one of the first electrode 121 and the second electrode 123 is a cathode. In some embodiments of the present disclosure, as shown in FIG. 5, the first electrode 121 is an anode, the second electrode 123 is a cathode, and the organic functional layer may include: a hole injection layer 221 and a hole transport layer 222 between the first electrode 121 and the organic light emitting layer 210, and an electron transport layer 223 and an electron injection layer 224 between the organic light emitting layer 210 and the second electrode 123. It should be noted that the structure shown in FIG. 5 is only an example, in other examples, the organic functional layer may alternatively include more or less film layers than those in FIG. 5, which is not limited in this embodiment.

The first electrodes 121 of any two adjacent light emitting devices 120 are spaced apart from each other in the spacing region between the two adjacent light emitting devices 120, i.e., the first electrodes 121 of the light emitting devices 120 are spaced apart from each other. The first electrode 121 of each light emitting device 120 corresponds to one pixel opening 114, and at least a part of the first electrode 121 is exposed at the lower port of the pixel opening 114. For example, an orthographic projection of the first electrode 121 on the base substrate 100 may cover an orthographic projection of the lower port of the pixel opening 114 on the base substrate 100 to form a region between an edge of the orthographic projection of the first electrode 121 on the base substrate 100 and an edge of the orthographic projection of the lower port of the pixel opening 114 on the base substrate 100, and the orthographic projection of the protrusion structure 130 on the base substrate 100 may be located in the region. At least a part of the organic light emitting functional layer 122 is located in the pixel opening 114 corresponding thereto, and is electrically connected to the first electrode 121 corresponding thereto. For example, the second electrodes 123 of the light emitting devices 120 may be formed as a whole layer so as to be of a one-piece structure.

The anode, as a connection layer for a positive voltage of the organic light emitting device 120, has a good conductivity and a high work function value. For example, for a top emission organic light emitting device, the anode thereof may include a metal film layer and a transparent conductive material having a high work function. The transparent conductive material may include indium tin oxide (ITO), or indium zinc oxide (IZO), or the like. For example, the first electrode 121 is an anode, and the structure of the first electrode 121 may be of a composite structure formed by titanium (Ti) thin film/titanium nitride (TiN) thin film/aluminum (Al) thin film/titanium nitride (TIN)/ITO thin film stacked sequentially, or be of a composite structure of Ti/Al/Ti/ITO.

The cathode, as a connection layer of a negative voltage of the organic light emitting device 120, has a good conductivity and a low work function value, and a material of the cathode may be determined according to the actual application scenario. For example, for the top emission organic light emitting device, the cathode may be made of a transparent conductive material, or a metal material with a low work function value, such as lithium, magnesium, calcium, strontium, aluminum, or indium, or an alloy of the metal material with the low work function value and copper, gold, or silver. For example, for a bottom emission light emitting device, the cathode may be made of the metal material having the low work function value.

In some embodiments of the present disclosure, the structure of the pixel defining layer 110 is not limited. For example, the pixel defining layer 110 may be of a single-layer structure or a composite structure of multiple layers. For example, the pixel defining layer 110 may include a plurality of inorganic film layers stacked, and the pixel openings 114 penetrates through the plurality of inorganic film layers stacked. Among the plurality of inorganic film layers stacked, a film layer farthest from the base substrate 100 is referred to as a top film layer.

In some embodiments of the present disclosure, a ratio (h1:h2) of a thickness of the protrusion structure 130 to a thickness of the top film layer in a direction perpendicular to the base substrate 100 may be from one ninth to one third. For example, h1:h2 may be 1:9, 1:6, or 1:3, or the like. For example, the thickness h1 of the protrusion structure 130 in the direction perpendicular to the base substrate 100 may range from 100 angstroms to 300 angstroms, such as 100 angstroms, 200 angstroms or 300 angstroms.

In some embodiments of the present disclosure, as shown in FIG. 2, the pixel defining layer 110 may include: a first inorganic film layer 111, a second inorganic film layer 112, and a third inorganic film layer 113 sequentially disposed along the direction away from the base substrate 100. The pixel openings 114 penetrate through the first inorganic film layer 111, the second inorganic film layer 112, and the third inorganic film layer 113. In this case, the third inorganic film layer 113 is a top film layer. For example, the first inorganic film layer 111 and the third inorganic film layer 113 may be silicon oxide (SiOₓ) layers, and the second inorganic film layer 112 may be a silicon nitride (SiNₓ) layer. For example, a material of the silicon oxide (SiOₓ) layer may include silicon oxide (SiO₂) and/or silicon monoxide (SiO), and a material of the silicon nitride (SiNₓ) layer may include SiN.

Alternatively, in other examples, the pixel defining layer 110 may include more or less layers than those shown in FIG. 2, for example, the pixel defining layer 110 may include four inorganic film layers, such as a silicon oxide layer, an aluminum oxide layer, a silicon nitride layer, and a silicon oxide layer, which are sequentially stacked, which is not limited in the embodiment.

As shown in FIG. 2, in order to space the first electrodes 121 of the adjacent light emitting devices 120 apart from each other, a layer of the first electrode 121 is patterned, that is, an electrode spacing groove 1211 is formed in the spacing region between the adjacent light emitting devices 120. The first inorganic film layer 111 of the pixel defining layer 110 may also play a role of lateral height coverage (LHC) for filling the electrode spacing groove 1211.

For example, as shown in FIG. 2, the pixel defining layer 110 may further include: an isolation groove 115 located in the spacing region between the adjacent light emitting devices 120. For example, the isolation groove 115 may be configured to space apart the hole injection layer 221 and the hole transport layer 222 in the organic light emitting functional layer 122 extending to the spacing region from each other, so as to further reduce the lateral current leakage and eliminate the color crosstalk among pixels. For example, the isolation groove 115 may be of an undercut structure, i.e., a groove with a top size smaller than a bottom size thereof as shown in FIG. 2.

In some embodiments of the present disclosure, the pixel openings 114 are formed by a dry etching process, such as a plasma etching process. The protrusion structures 130 may be formed by the accumulation of an insulating polymer generated when the pixel openings 114 are formed by the dry etching process. In this case, each protrusion structure 130 is a byproduct of the process of forming the pixel opening 114 by dry etching the thin film layers of the pixel defining layer 110, so that no additional materials, machines and processes are required. Moreover, the protrusion structures 130 may be formed by photolithography and dry etching processes in synchronization with the pixel openings 114 of the pixel defining layer 110, and have a self-aligned structure without overlay error.

For example, the pixel defining layer 110 is an inorganic insulating layer, and the dry etching process may be a plasma etching process. The plasma etching process is to activate the reaction gas into the active particles, such as atoms or radicals, by high-frequency glow discharge reaction, where the active particles are diffused to the part to be etched and react with the material to be etched to form a volatile reactant to be removed.

It should be noted that the plasma dry etching adopts two etching modes: (1) physical bombardment etching; and (2) chemical etching. By adjusting process parameters of the etching menu on a dry etching menu interface of a plasma etching device, whether the physical bombardment etching or the chemical etching is mainly used can be determined.

The etching of the pixel openings 114 in the pixel defining layer 110 may be mainly the plasma bombardment etching, that is, the physical bombardment etching, in which the plasma bombards a patterned photoresist material layer (such as photoresist) and the top film layer (such as SiO₂) that is not shielded by the photoresist material layer, the photoresist has the thinnest side, the photoresist on the side is consumed by plasma bombardment, and the SiO₂ at the edge of the pixel opening 114 is exposed. An area of the side of the photoresist in contact with the polymer generated by the plasma bombardment is greatest, so that the polymer generated through the dry etching is accumulated on the SiO₂ at the edge of the etched pixel opening 114, thereby forming the pixel opening 114 and an anti-leakage protection structure, i.e., the protrusion structure 130, at the periphery of the pixel opening 114.

It should be noted that when the dry etching is performed by mainly using the chemical etching method, the physical plasma bombardment in the chemical etching method is less, and the polymers generated by etching are less, so that the accumulation of the polymers is not easily.

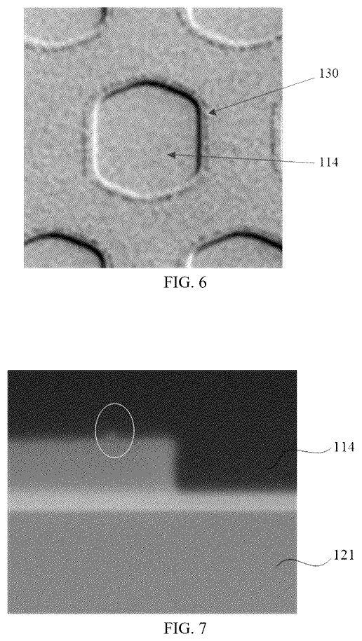

For example, FIG. 6 illustrates a plan micrograph of a pixel opening 114 according to some embodiments of the present disclosure; FIG. 7 illustrates a cross-sectional micrograph at a pixel opening 114 according to some embodiments of the present disclosure. As shown in FIG. 6, after the pixel opening 114 is formed in the pixel defining layer 110 by using the dry etching process, the polymer is accumulated at the periphery of the pixel opening 114 as the protrusion structure 130. As can be seen in FIG. 7, a cross-sectional shape of the protrusion structure 130 (at a location marked with a white circle in FIG. 7) may be square or square-like.

In some embodiments of the present disclosure, since the accumulated polymer is easily moved by a shrinkage stress of removing the photoresist material layer such as the photoresist during the process of removing the photoresist material layer, the protrusion structure 130 has a certain distance from the upper port of the pixel opening 114 corresponding thereto. In some embodiments of the present disclosure, by controlling a thickness of the photoresist material layer remained after etching, the shrinkage stress generated during the process of removing the photoresist material layer may be adjusted, so as to control the distance, so as to ensure the leakage blocking performance of the protrusion structure 130. For example, the distance may be controlled to be between 10 nm and 30 nm.

In some embodiments of the present disclosure, the material of the protrusion structure 130 may include at least: atoms in the reactive gas used in the dry etching process and atoms in the photoresist material used in the dry etching process.

The reactive gas used in the plasma etching process is determined according to the material to be etched. For example, the pixel defining layer 110 may include: the silicon oxide layer, the silicon nitride layer, and the silicon oxide layer which are stacked, and the reaction gas used in the plasma etching process may be tetrafluoromethane (CF₄). CF₄ is decomposed into various neutral groups or ions such as CF₃, CF₂, CF, F, C and their ions under the collision of high energy electrons. The active particles bombard a surface of the material to be etched on one hand and chemically react on the surface of the material to be etched on the other hand. In this case, since the reaction gas contains C (carbon) and F (fluorine), the material composition of the protrusion structure 130 may include C (carbon) and F. If the photoresist material is a photoresist (PR) containing C and O (oxygen), the material composition of the protrusion structure 130 may include C and O.

In some embodiments of the present disclosure, in addition to the reaction gas and the material composition of the photoresist material, the material composition of the protrusion structure 130 may further include: at least a portion of a material composition of the pixel defining layer 110, which is determined according to the structure and material of the actual pixel defining layer 110. For example, when the pixel defining layer 110 has a composite structure formed by stacking a plurality of layers, the polymer generated when etching the top film layer is easily accumulated on the edge of the pixel opening 114, and thus, the material composition of the protrusion structure 130 may further include: a material composition of the top film layer in the pixel defining layer 110. For example, when the top film layer is made of silicon oxide, the silicon oxide containing Si (silicon) and O, and in this case, the material composition of the protrusion structure 130 may further include: Si and O.

In some embodiments of the present disclosure, when the reaction gas used in the plasma etching process is CF₄, the adopted photoresist material is the photoresist, and the top film layer of the pixel defining layer 110 is made of silicon oxide, a material composition of the polymer generated by dry etching may at least include C, F, Si and O, belonging to the insulating substance, i.e., the material composition of the above protrusion structure 130 may at least include C, F, Si and O.

In some embodiments of the present disclosure, the display substrate 10 may be used in the field of the micro OLED display, and accordingly, the base substrate 100 may be a silicon wafer. For example, a material of the silicon wafer may be monocrystalline silicon, and a planar shape of the silicon wafer may be a circular shape, or other shapes. In this case, a driving circuit layer may be formed on the base substrate 100, thereby forming a back plate including the driving circuit layer. The driving circuit layer includes: pixel driving circuits corresponding to the light emitting devices 120 one to one. The pixel driving circuit is connected to the first electrode 121 of the light emitting device 120 through a conductive part 101 to drive the light emitting device 120 to emit light.

For example, each pixel driving circuit may include a plurality of electronic elements such as transistors and a capacitor. For example, each pixel driving circuit may include three transistors and one capacitor, constituting 3T1C (i.e., one driving transistor, two switching transistors, and one capacitor) structure. Alternatively, each pixel driving circuit may include more than three transistors and at least one capacitor, so as to constitute, for example, 4T1C (i.e., one driving transistor, three switching transistors and one capacitor) structure, 5T1C (i.e., one driving transistor, four switching transistors and one capacitor) structure, or 7T1C (i.e., one driving transistor, six switching transistors and one capacitor) structure, or the like. The transistor may be a thin film transistor (TFT), a metal oxide semiconductor (MOS), or other switching device with the same characteristics.

Alternatively, in other embodiments of the present disclosure, the base substrate 100 may be a rigid substrate such as a glass substrate, a quartz substrate, or a resin substrate. Alternatively, the display substrate 10 may be a flexible substrate, so that the display substrate 10 may be applied to the field of flexible display. For example, in the case that the display substrate 10 is a flexible substrate, the base substrate may include an organic material, such as PI (polyimide), PET (polyethylene terephthalate), PEN (polyethylene naphthalate) or the like.

As shown in FIG. 2, in some embodiments of the present disclosure, the display substrate 10 may further include an encapsulation layer 140 located on a side of the second electrode 123 of the light emitting device 120 away from the base substrate 100. The encapsulation layer 140 may encapsulate the display substrate 10, to prevent external water, oxygen, and the like from entering the interior of the display substrate 10, thereby protecting components (e.g., organic light emitting devices) inside the display substrate 10.

In some embodiments, the encapsulation layer 140 may include a first encapsulation layer and a second encapsulation layer that are alternately stacked. For example, the first encapsulation layer and the second encapsulation layer each may be made of an inorganic material, such as nitride, oxide, oxynitride, nitrate, carbide, or any combination thereof. For example, the first encapsulation layer may be formed, for example, as a silicon nitride film, by a chemical vapor deposition (CVD) process, and the second encapsulation layer may be formed, for example, as an aluminum oxide film, by an atomic layer deposition process, and a plurality of silicon nitride films and a plurality of aluminum oxide films are alternately stacked.

In other embodiments, the encapsulation layer 140 may include a first encapsulation layer, a second encapsulation layer, and a third encapsulation layer, which are sequentially stacked. A material of the first encapsulation layer and the third encapsulation layer may include an inorganic material, for example, silicon nitride, silicon oxide, silicon oxynitride, or the like, and the inorganic material has high density and can prevent intrusion of water, oxygen, or the like. For example, the first encapsulation layer and the third encapsulation layer may be formed by a chemical vapor deposition or the like.

For example, a material of the second encapsulation layer may be a polymer material containing a desiccant, or a polymer material capable of blocking moisture, or the like, such as a polymer resin, or may be a water-absorbing material, such as an alkali metal (e.g., Li or Na), an alkaline earth metal (e.g., Ba or Ca), or other moisture-reactive metals (e.g., Al or Fe); or may be alkali metal oxides (e.g., Li₂O or Na₂O), alkaline earth metal oxides (e.g., MgO, CaO, or BaO), sulphates (e.g., anhydrous MgSO₄), metal halides (e.g., CaCl₂), or perchlorates (e.g., Mg(ClO₄)₂), or the like. A surface of the display substrate 10 may be planarized by the second encapsulation layer, to relieve stress of the first encapsulation layer and the third encapsulation layer. The second encapsulation layer may be provided therein with a material such as a desiccant, which can absorb substances such as water and oxygen that entered the interior thereof, thereby protecting the components (such as the organic light emitting functional layer 122) in the display substrate 10.

For example, as shown in FIG. 2, in some embodiments of the present disclosure, the display substrate 10 may further include a color filter layer 160, and the color filter layer 160 may be disposed on a side of the encapsulation layer 140 away from the base substrate 100. The color filter layer 160 may include a plurality of color filter units, each color filter unit corresponding to one sub-pixel, for example, a red sub-pixel R corresponds to a red filter unit 162, a green sub-pixel G corresponds to a green filter unit 163, and a blue sub-pixel B corresponds to a blue filter unit 161.

As shown in FIG. 2, in some embodiments of the present disclosure, the display substrate 10 may further include: a first planarization layer 150, the first planarization layer 150 is disposed between the encapsulation layer 140 and the color filter layer 160 for planarization, so as to improve the thickness uniformity of the color filter layer 160.

In some embodiments of the present disclosure, the display substrate 10 may further include: micro-lenses 180 arranged in an array. As shown in FIG. 2, the array of micro-lenses 180 may be disposed on a side of the color filter layer 160 away from the base substrate 100. The micro-lens array may be configured to converge the lateral light, to improve the display brightness and reduce the power consumption. For example, each micro-lens 180 may be disposed corresponding one sub-pixel. For example, the micro-lens 180 may be a plano-convex lens structure, which may be formed by spin coating a material film for the micro-lens, exposing, developing, and thermoforming processes.

As shown in FIG. 2, in some embodiments of the present disclosure, the display substrate 10 may further include: a second planarization layer 170 disposed between the color filter layer 160 and the array of micro-lenses 180 for planarization, to improve the thickness uniformity of the material film layer for the micro-lens, thereby improving the processing precision of the array of the micro-lenses 180.

Still referring to FIG. 2, some embodiments of the present disclosure provide a display substrate 10, and the display substrate 10 may include: a base substrate 100, and a pixel defining layer 110 and a plurality of light emitting devices 120 on the base substrate 100. The pixel defining layer 110 includes a plurality of pixel openings 114, and each light emitting device 120 is located at one pixel opening 114. Each light emitting device 120 includes a first electrode 121, an organic light emitting functional layer 122, and a second electrode 123, which are stacked, the first electrodes 121 of any two adjacent light emitting devices 120 are spaced apart from each other in a spacing region between the two adjacent light emitting devices 120, and the organic light emitting functional layer 122 covers the pixel opening 114 and extends to the spacing region between the adjacent light emitting devices 120. At least a part of the first electrode 121 is exposed at a lower port of each pixel opening 114. A periphery of an upper port of each pixel opening 114 is provided with a protrusion structure 130 surrounding the pixel opening 114. The protrusion structure 130 is formed by accumulation of an insulating polymer generated during etching the pixel opening 114, and the protrusion structure 130 is configured to block a leakage path from the first electrode 121 exposed at the pixel opening 114 to the spacing region between the adjacent light emitting devices 120. It should be noted that the structure of the display substrate 10 may refer to the description in the above embodiments, and is not repeated herein.

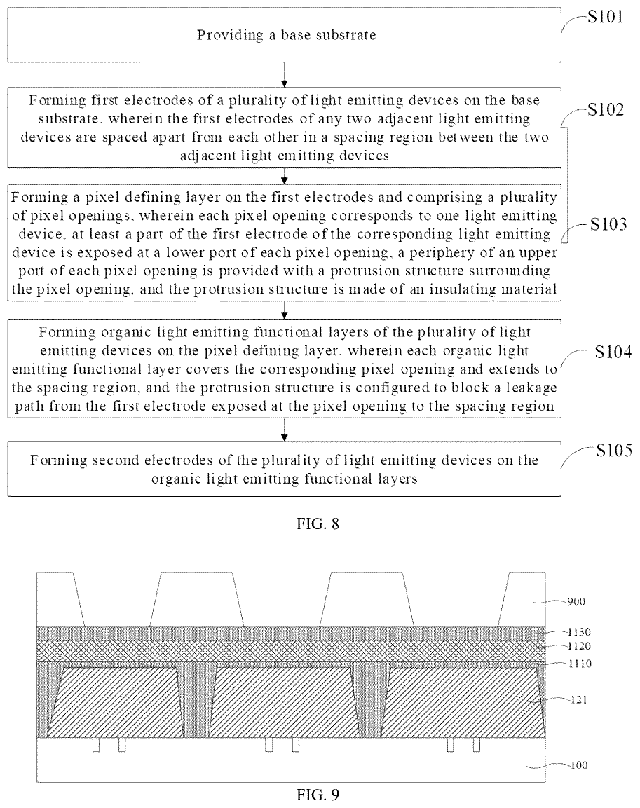

FIG. 8 illustrates a flow chart of a method for manufacturing the display substrate 10 according to some embodiments of the present disclosure. As shown in FIG. 8, some embodiments of the present disclosure provide a method for manufacturing the display substrate 10, which is used to manufacture the display substrate 10 provided in the above embodiments. The method may include steps S101 to S105.

In the step S101, a base substrate is provided;

In the step S102, first electrodes of a plurality of light emitting devices are formed on a base substrate, wherein the first electrodes of any two adjacent light emitting devices are spaced apart from each other in a spacing region between the two adjacent light emitting devices.

In the step S103, a pixel defining layer is formed on the first electrodes, where the pixel defining layer has a plurality of pixel openings, each pixel opening corresponds to one light emitting device, at least a part of the first electrode of the light emitting device 120 corresponding to the pixel opening is exposed at a lower port of the pixel opening, a periphery of an upper port of each pixel opening is provided with a protrusion structure surrounding the pixel opening, and the protrusion structure is made of an insulating material.

In the step S104, organic light emitting functional layers of a plurality of light emitting devices are formed on the pixel defining layer, where each organic light emitting functional layer covers the pixel opening corresponding thereto and extends to the spacing region, and the protrusion structure is configured to block a leakage path from the first electrode exposed at the pixel opening to the spacing region.

In the step S105, second electrodes of the plurality of light emitting devices are formed on the organic light emitting functional layers.

In some embodiments of the present disclosure, the process of forming the pixel defining layer 110 on the first electrodes 121 may include: forming a transition layer of the pixel defining layer 110 on the first electrodes 121, and etching the transition layer through a plasma etching process to form the plurality of pixel openings 114, where an insulating polymer generated in the etching process is accumulated at the periphery of upper ports of the pixel openings 114 to form the protrusion structures 130.

The transition layer may be a single-layer structure, or a composite structure of multiple layers. In some embodiments of the present disclosure, the transition layer may include: a first silicon oxide thin film, a silicon nitride thin film, and a second silicon oxide thin film which are stacked in a direction away from the base substrate 100, and in this case, the insulating polymer generated in the process of etching the second silicon oxide thin film is accumulated at the periphery of the upper ports of the pixel openings 114, thereby forming the protrusion structures 130.

In some embodiments of the present disclosure, before etching the transition layer through the plasma etching process to form the plurality of pixel openings 114, the method may further include: forming a patterned photoresist material layer on the transition layer. In this case, the etching the transition layer through the plasma etching process to form the plurality of pixel openings 114 and the protrusion structures 130 may include: etching a region which is not shielded by the photoresist material layer by the plasma etching process to form the plurality of pixel openings 114 and the insulating polymer accumulated at the periphery of the upper ports of the pixel openings 114, and then, removing the photoresist material layer. Under the effect of the shrinkage stress generated by removing the photoresist material layer, the accumulated insulating polymer moves in a direction away from the pixel opening 114 corresponding thereto, thereby obtaining the protrusion structure 130. In some embodiments of the present disclosure, a distance that the insulating polymer moves may be controlled to be between 10 nm and 30 nm.

In some embodiments of the present disclosure, by controlling a thickness of the photoresist material layer remained after etching, the shrinkage stress generated during the process of removing the photoresist material layer may be adjusted, so as to control the distance that the insulating polymer moves due to removal of the photoresist material layer, that is, control the distance between each protrusion structure 130 and the edge of the pixel opening 114 corresponding thereto, so that the protrusion structure 130 can increase the physical insulation height of the pixel defining layer 110, thereby ensuring the leakage blocking performance of the protrusion structure 130.

By taking a case where the transition layer of the pixel definition layer 110 includes: the first silicon oxide thin film 1110, the silicon nitride thin film 1120 and the second silicon oxide thin film 1130 which are stacked in the direction away from the base substrate 100, and the photoresist material is a photoresist as an example, the process for forming the pixel openings 114 and the protrusion structures 130 will be described below.

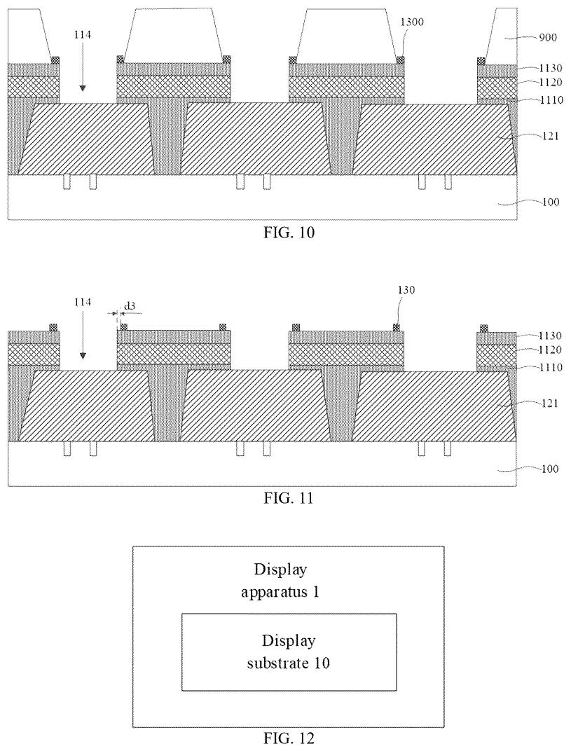

FIG. 9 illustrates a schematic diagram of a structure with a patterned photoresist material layer according to some embodiments of the present disclosure; FIG. 10 illustrates a schematic diagram of a structure after being etched by a dry etching according to some embodiments of the present disclosure; FIG. 11 illustrates a schematic diagram of a structure after the photoresist being removed according to some embodiments of the present disclosure.

As shown in FIG. 9, a photoresist layer 900 is spin-coated on the second silicon oxide thin film 1130, such as SiO₂, of the pixel defining layer 110, and patterns of the pixel openings 114 are formed in the photoresist layer 900 through exposure, development and other processes.

Then, the patterns in the photoresist are transferred to the transition layer of the pixel defining layer 110 by the plasma etching process, so as to obtain the pixel openings 114. In the process, the plasma bombards the photoresist layer 900 and the SiO₂ uncovered by the photoresist layer 900, a side edge of the patterned photoresist layer 900 is a slope with a relatively small thickness, the photoresist at the side edge is consumed by the plasma bombardment, the SiO₂ at the edges of the patterns of the pixel openings 114 is exposed, and a contact area between the side edge of the photoresist and the polymer generated by the plasma bombardment is the greatest, so that the polymer 1300 generated by the dry etching may be accumulated as a circle on the SiO₂ exposed at the edge of the pixel opening 114, as shown in FIG. 10. The material composition of polymer 1300 includes at least C, F, Si and O, therefore, the polymer 1300 is an insulating substance and can be used as an anti-leakage protection structure.

Next, the photoresist layer 900 is removed. As shown in FIG. 11, since the polymer accumulated during the dry etching is moved due to a shrinkage stress of removing the photoresist layer 900 during the process of removing the photoresist layer 900, each resulted protrusion structure 130 has a certain distance d3 from the edge of the pixel opening 114 corresponding thereto. By controlling a thickness of the photoresist remained after etching, a shrinkage stress generated during the process of removing the photoresist layer 900 may be adjusted, so as to control the distance d3 between each resulted protrusion structure 130 and the edge of the pixel opening 114 corresponding thereto be between 10 nm and 30 nm.

For example, FIG. 12 illustrates a schematic diagram of a display apparatus according to some embodiments of the present disclosure. As shown in FIG. 12, the display apparatus 1 includes the display substrate 10 provided in any one of the above embodiments. Thus, the display apparatus 1 has technical effects corresponding to the beneficial technical effects of the display substrate 10 described above.

The display apparatus 1 may be any electronic product or component with a display function, such as a display screen, a mobile phone, a notebook computer, a tablet computer, a wearable display apparatus (e.g., a VR device, an AR device, etc.), a television, or a digital photo frame, or the like.

It should be noted that not all the structures of the display apparatus 1 are described in detail here. In order to realize the necessary functions of the display apparatus 1, one ordinary skill in the art may provide other structures according to practical applications, which is not limited in the embodiment of the present disclosure.

Some embodiments of the present disclosure provide a display substrate 10, a method for manufacturing the same, and a display apparatus, and may have at least one of the following advantages:
(1) In the display substrate 10 provided in some embodiments of the present disclosure, the protrusion structure 130 can effectively block the leakage path from the first electrode 121 exposed at the pixel opening 114 to the spacing region between the adjacent pixels, which is beneficial to reducing the color crosstalk interference of light among pixels, so as to improve the display effect.
(2) In the display substrate 10 provided in some embodiments of the present disclosure, the protrusion structures 130 may be formed by the accumulation of an insulating polymer generated when the pixel openings 114 are etched, and therefore, are byproducts of the dry etching process, and no additional materials, machines and processes are required. Moreover, the protrusion structures 130 may be formed by photolithography and dry etching processes in synchronization with the pixel openings 114 of the pixel defining layer 110, and have a self-aligned structure without overlay error.
(3) In the method for manufacturing the display substrate 10 according to some embodiments of the present disclosure, by controlling the thickness of the photoresist material layer remained after etching, a shrinkage stress generated during the process of removing the photoresist material layer may be adjusted, so as to achieve the purpose of controlling the distance between the protrusion structure 130 and the edge of the pixel opening 114 corresponding to the protrusion structure 130, so that the protrusion structure 130 can increase the physical insulation height of the pixel defining layer 110, thereby ensuring the leakage blocking performance of the protrusion structure 130.

It should be noted that the drawings of the embodiments of the present disclosure only relate to the structures related to the embodiments of the present disclosure, and other structures may be provided with reference to general designs. Without conflict, the embodiments of the present disclosure and features of the embodiments may be combined with each other to obtain new embodiments.

While several embodiments of the present disclosure have been described, additional variations and modifications in those embodiments may occur to one ordinary skill in the art once they learn of the basic inventive concepts. Therefore, the appended claims are intended to be interpreted as including the preferred embodiments and all variations and modifications that fall within the scope of the present disclosure.

1. A display substrate, comprising:
a base substrate;
a pixel defining layer on the base substrate and comprising a plurality of pixel openings; and
a plurality of light emitting devices, wherein each light emitting device is located at one pixel opening, each light emitting device comprises a first electrode, an organic light emitting functional layer, and a second electrode, which are stacked, the first electrodes of any two adjacent light emitting devices are spaced apart from each other in a spacing region between the two adjacent light emitting devices, and the organic light emitting functional layer covers a corresponding pixel opening and extends to the spacing region;
wherein at least a part of the first electrode is exposed at a lower port of the pixel opening, a periphery of an upper port of each pixel opening is provided with a protrusion structure surrounding the pixel opening, the protrusion structure is located between the pixel opening and the spacing region, the protrusion structure is made of an insulating material, and the protrusion structure is configured to block a leakage path from the first electrode exposed at the pixel opening to the spacing region.

2. The display substrate of claim 1, wherein each protrusion structure is formed by an accumulation of a polymer generated during etching the corresponding pixel opening by a dry etching process, and a material composition of the protrusion structure at least comprises: a composition of a reaction gas and a composition of a photoresist material used in the dry etching process.

3. The display substrate of claim 2, wherein the pixel defining layer comprises a plurality of inorganic film layers stacked, the plurality of pixel openings penetrate through the plurality of inorganic film layers stacked, and a material composition of the protrusion structure further comprises a material composition of a top film layer of the pixel defining layer, wherein the top film layer is a layer of the pixel defining layer farthest from the base substrate.

4. The display substrate of claim 3, wherein the pixel defining layer comprises: a first inorganic film layer, a second inorganic film layer and a third inorganic film layer which are sequentially arranged along a direction away from the base substrate, the third inorganic film layer is the top film layer, and the plurality of pixel openings penetrate through the first inorganic film layer, the second inorganic film layer and the third inorganic film layer; and
the third inorganic film layer is a silicon oxide layer, and the material component of the protrusion structure comprises: carbon, fluorine, oxygen, and silicon.

5. The display substrate of claim 3, wherein a ratio of a thickness of the protrusion structure to a thickness of the top film layer in a direction perpendicular to the base substrate is between one ninth and one third.

6. The display substrate of claim 1, wherein a thickness of the protrusion structure in a direction perpendicular to the base substrate is between 100 angstroms and 300 angstroms.

7. The display substrate of claim 1, wherein an orthographic projection of the protrusion structure on the base substrate is in a closed ring shape, and a width of the closed ring shape is between 10 nm and 30 nm.

8. The display substrate of claim 1, wherein an orthographic projection of the protrusion structure on the base substrate is in a closed ring shape, and a ratio of a width of the closed ring shape to a spacing width between two adjacent light emitting devices is between one fiftieth and one two-hundredth.

9. The display substrate of claim 1, wherein a distance between the protrusion structure and the pixel opening surrounded by the protrusion structure is in a range from 10 nm to 30 nm.

10. A display substrate, comprising:
a base substrate;
a pixel defining layer on the base substrate and comprising a plurality of pixel openings; and
a plurality of light emitting devices, wherein each light emitting device is located at one pixel opening, each light emitting device comprises a first electrode, an organic light emitting functional layer, and a second electrode, which are stacked, the first electrodes of any two adjacent light emitting devices are spaced apart from each other in a spacing region between the two adjacent light emitting devices, and the organic light emitting functional layer covers a corresponding pixel opening and extends to the spacing region;
wherein at least a part of the first electrode is exposed at a lower port of the pixel opening, a periphery of an upper port of each pixel opening is provided with a protrusion structure surrounding the pixel opening, each protrusion structure is formed by an accumulation of a polymer generated during etching the corresponding pixel opening, and the protrusion structure is configured to block a leakage path from the first electrode exposed at the pixel opening to the spacing region.

11. A display apparatus, comprising: the display substrate of claim 1.

12. A method for manufacturing a display substrate, comprising:
providing a base substrate;
forming first electrodes of a plurality of light emitting devices on the base substrate, wherein the first electrodes of any two adjacent light emitting devices are spaced apart from each other in a spacing region between the two adjacent light emitting devices;
forming a pixel defining layer on the first electrodes and comprising a plurality of pixel openings, wherein each pixel opening corresponds to one light emitting device, at least a part of the first electrode of the light emitting device is exposed at a lower port of the pixel opening corresponding to the light emitting device, a periphery of an upper port of each pixel opening is provided with a protrusion structure surrounding the pixel opening, and the protrusion structure is made of an insulating material;
forming organic light emitting functional layers of the plurality of light emitting devices on the pixel defining layer, wherein each organic light emitting functional layer covers the corresponding pixel opening and extends to the spacing region, and the protrusion structure is configured to block a leakage path from the first electrode exposed at the pixel opening to the spacing region; and
forming second electrodes of the plurality of light emitting devices on the organic light emitting functional layers.

13. The method of claim 12, wherein the forming a pixel defining layer on the first electrodes comprises:
forming a transition film layer of the pixel defining layer on the first electrodes; and
etching the transition film layer by a plasma etching process to form the plurality of pixel openings, wherein an insulating polymer generated in the etching process is accumulated at the periphery of the upper port of each pixel opening to form the protrusion structure.

14. The method of claim 13, wherein the transition film layer comprises: a first silicon oxide thin film, a silicon nitride thin film and a second silicon oxide thin film which are stacked in a direction away from the base substrate, and the insulating polymer generated in the etching process being accumulated at the periphery of the upper port of each pixel opening to form the protrusion structure comprises:
the insulating polymer generated in the process of etching the second silicon oxide thin film is accumulated at the periphery of the upper port of each pixel opening to form the protrusion structure.

15. The method of claim 13, wherein before etching the transition film layer by the plasma etching process to form the plurality of pixel openings, the method further comprises:
forming a patterned photoresist material layer on the transition film layer; and
etching the transition film layer by the plasma etching process to form the plurality of pixel openings and the protrusion structures, comprising:
etching a region which is not shielded by the photoresist material layer by the plasma etching process to form the plurality of pixel openings and the insulating polymer accumulated at the periphery of the upper port of each pixel opening; and
removing the photoresist material layer, wherein the accumulated insulating polymer moves away from the corresponding pixel opening under the action of shrinkage stress generated by removing the photoresist material layer to obtain the protrusion structure, and a distance that the accumulated insulating polymer moves is in a range from 10 nm to 30 nm.

16. A display apparatus, comprising: the display substrate of claim 10.

17. The method of claim 12, wherein a material component of the protrusion structure comprises: carbon, fluorine, oxygen, and silicon.

18. The method of claim 12, wherein a thickness of the protrusion structure in a direction perpendicular to the base substrate is between 100 angstroms and 300 angstroms.

19. The method of claim 12, wherein an orthographic projection of the protrusion structure on the base substrate is in a closed ring shape, and a width of the closed ring shape is between 10 nm and 30 nm.

20. The method of claim 12, wherein an orthographic projection of the protrusion structure on the base substrate is in a closed ring shape, and a ratio of a width of the closed ring shape to a spacing width between two adjacent light emitting devices is between one fiftieth and one two-hundredth.
